(19) United States
(12) Patent Application Publication
(10) Pub. No.: US 2022/0088833 A1
(43) Pub. Date: Mar. 24, 2022

(54) IMPRINTING METHOD FOR IMPROVING DEMOLDING STABILITY AND THE RELATED SYSTEM

(71) Applicant: EVER RADIANT INCORPORATION, Tainan City (TW)

(72) Inventor: Sung-Wen TSAI, Tainan City (TW)

(21) Appl. No.: 17/537,986

(22) Filed: Nov. 30, 2021

Related U.S. Application Data
(63) Continuation-in-part of application No. 16/738,201, filed on Jan. 9, 2020.
Application No. 16/738,201 is a continuation-in-part of application No. 17/197,255, filed on Mar. 10, 2021.

(30) Foreign Application Priority Data
May 12, 2021 (TW) 110117162

(51) Int. Cl. B29C 33/38; B29C 59/02; B29C 59/00

(52) U.S. Cl. CPC B29C 33/3842; B29C 59/002; B29C 59/02

(57) ABSTRACT

An imprinting method includes the steps of: adding a soluble material to a master mold; solidifying the soluble material to form a soluble mold; positioning an adhesive on a side of the soluble mold opposite to the master mold; attaching a taking device to the adhesive; removing the taking device from the master mold together with the soluble mold; positioning the soluble mold on a polymer layer; applying a first high temperature and a pressure to the soluble mold to form a transferred pattern corresponding to a convex-concave pattern of the soluble mold on the polymer layer and separate a support plate and a tape of the taking device; applying a second high temperature to the soluble mold to solidify the polymer layer; and dissolving the soluble mold by using a solvent to separate the solidified polymer layer and the support plate.

### CROSS REFERENCE

This non-provisional application is a Continuation-in-Part of American Non-Provisional application Ser. No. 16/738,201, filed on Jan. 9, 2020, and a Continuation-in-Part of American Non-Provisional application Ser. No. 17/197,255, filed on Mar. 10, 2021, the contents thereof are incorporated by reference herein. This non-provisional application also claims priority of Taiwan Invention Patent Application No. 110117162, filed on May 12, 2021, the contents thereof are incorporated by reference herein.

### FIELD OF THE INVENTION

The present invention is pertinent to an imprinting method, and particularly to an imprinting method for improving demolding stability and the related system.

### BACKGROUND OF THE INVENTION

Imprinting is performed to form a pattern on an imprinting material positioned on a substrate by using a mold. During thermal imprinting, polymer resin is heated to a temperature higher than its glass transition temperature (Tg) and then a mold is placed on the polymer resin. After which, the polymer resin is cooled down to a temperature lower than its glass transition temperature and then the mold is removed from the polymer resin so that a fine pattern is formed on the polymer resin positioned on the substrate. As described in S. Chou et al., Appl. Phys. Lett. 67, 3114 (1995), thermoplastic resin is used as a processed material for thermal imprinting. As described in J. Haisma et al., J. Vac. Sci. Technol. B 14(6), 4124 (1996), a curable composition is provided for light imprinting.

Demolding is also called “mold release”, which is a process for removing a mold from a transferred article. Since the imprinting method contains the demolding step, demolding efficiency is significant and has effects on mold maintenance and transferred pattern completeness. As described in M. W. Lin et al., J. Micro/Nanolith. MEMS MOEMS 7(3), 033005 (2008), a curable composition is provided, which includes a monomer containing a fluorine element or a non-reactive compound containing a fluorine element to improve demolding efficiency. American Patent U.S. Pat. No. 6,849,558B2 and American Patent Publication US2006/0249886A1 disclose a soluble mold. Such soluble mold is produced by injecting a soluble material into a master mold to cure and then removing the mold from the master mold by using a preform. As described in Journal of Vacuum Science & Technology B 21, 2961 (2003), the preform is made of the same material as the soluble material, and it must be attached to the soluble material before the soluble material is completely cured. Generally, the concentration and the thickness of the soluble material have effects on the curing time, and therefore it depends on the operator's expertise and experience at what curing extent the preform is attached to the soluble material.

Molecular transfer lithography is performed by patterning a photoresist layer by using exposure and development, and then transferring a geometric pattern from a photomask to the photoresist positioned on the substrate. Molecular transfer lithography can accurately control the shape and the size of the formed pattern and is an important process for the semiconductor field. As described in Nanotechnology 24 (2013) 085302 (6pp), although the mold is soluble, it needs to be evenly distributed on the article by using a roller. This leads to the formed fine structure deformation resulted from the structure space expansion.

### SUMMARY OF THE INVENTION

An objective of the present invention is to provide an imprinting method, which can prevent the mold from being deformed, shifted, or expanded so that the transferred article corresponding to the mold has no structure defect.

Therefore, the present invention provides an imprinting method, which includes the steps of: adding a soluble material to a master mold; solidifying the soluble material to form a soluble mold, the soluble mold having a convex-concave pattern; positioning an adhesive on a side of the soluble mold opposite to the master mold; attaching a taking device to the adhesive, the taking device comprising a frame, a tape connected to the frame, and a support plate connected to the tape, wherein the taking device is attached to the adhesive through contact of the support plate with the adhesive; removing the taking device from the master mold together with the soluble mold; positioning the soluble mold on a polymer layer; applying a first high temperature and a pressure to the soluble mold to form a transferred pattern corresponding to the convex-concave pattern on the polymer layer and separate the support plate and the tape; applying a second high temperature to the soluble mold to solidify the polymer layer, wherein the first high temperature is different from the second high temperature; and dissolving the soluble mold by using a solvent to separate the solidified polymer layer and the support plate so as to form a transferred article having the transferred pattern.

Preferably, on the condition that the first high temperature is higher than the second high temperature, the time for the applying step of the first high temperature is greater than that for the applying step of the second high temperature, the time for the applying step of the first high temperature is equivalent to that for the applying step of the second high temperature, or the time for the applying step of the first high temperature is lower than that for the applying step of the second high temperature; or on the condition that the first high temperature is lower than the second high temperature, the time for the applying step of the first high temperature is greater than that for the applying step of the second high temperature, the time for the applying step of the first high temperature is equivalent to that for the applying step of the second high temperature, or the time for the applying step of the first high temperature is lower than that for the applying step of the second high temperature.

Preferably, the first high temperature is from 60° C. to 150° C., and the time for the applying step of the first high temperature and the pressure is from 0.5 minute to 30 minutes.

Preferably, the second high temperature is from 60° C. to 180° C., and the time for the applying step of the second high temperature is from 1 minute to 600 minutes.

Preferably, the soluble mold has a first alignment mark, and the positioning step of the soluble mold on the polymer layer comprises the steps of: positioning an article for transfer on a working platform, wherein the article for transfer comprises: a substrate positioned on the working platform and the polymer layer positioned on the substrate, and the substrate has a second alignment mark; determining whether the first alignment mark and the second alignment mark are aligned with each other by using a camera positioned on a side of the taking device opposite to the soluble mold or by using another camera positioned on a side of the working platform opposite to the article for transfer; and if the two alignment marks are aligned with each other, contacting the soluble mold with the polymer layer; or if the two alignment marks are not aligned with each other, adjusting an x-axis position and a y-axis position of the soluble mold and a θ angle formed between the soluble mold and an x-y plane defined by the working platform, until the two alignment marks are aligned with each other.

Preferably, the soluble mold has a first alignment mark, and the positioning step of the soluble mold on the polymer layer comprises the steps of: positioning an article for transfer on a working platform, wherein the article for transfer comprises: a substrate positioned on the working platform and the polymer layer positioned on the substrate, and the substrate has a second alignment mark; contacting the soluble mold with the polymer layer; and determining whether the first alignment mark and the second alignment mark are aligned with each other by using a camera positioned on a side of the taking device opposite to the soluble mold or by using another camera positioned on a side of the working platform opposite to the article for transfer; and if the two alignment marks are not aligned with each other, adjusting an x-axis position and a y-axis position of the soluble mold and a θ angle formed between the soluble mold and an x-y plane defined by the working platform, until the two alignment marks are aligned with each other.

Preferably, the soluble mold has a first alignment mark, and the positioning step of the soluble mold on the polymer layer comprises the steps of: positioning an article for transfer on a working platform, wherein the article for transfer comprises: a substrate positioned on the working platform and the polymer layer positioned on the substrate, and the substrate has a second alignment mark; moving a camera to a position between the soluble mold and the article for transfer to determine whether the first alignment mark and the second alignment mark are aligned with each other; and if the two alignment marks are aligned with each other, restoring the position of the camera, and then contacting the soluble mold with the polymer layer; or if the two alignment marks are not aligned with each other, adjusting an x-axis position and a y-axis position of the soluble mold and a θ angle formed between the soluble mold and an x-y plane defined by the working platform, until the two alignment marks are aligned with each other.

Preferably, the soluble mold has a first alignment mark, and the positioning step of the soluble mold on the polymer layer comprises the steps of: positioning an article for transfer on a working platform, wherein the article for transfer comprises: a substrate positioned on the working platform and the polymer layer positioned on the substrate, and the working platform has a third alignment mark; determining whether the first alignment mark and the third alignment mark are aligned with each other by using a camera positioned on a side of the taking device opposite to the soluble mold or by using another camera positioned on a side of the working platform opposite to the article for transfer; and if the two alignment marks are aligned with each other, contacting the soluble mold with the polymer layer; or if the two alignment marks are not aligned with each other, adjusting an x-axis position and a y-axis position of the soluble mold and a θ angle formed between the soluble mold and an x-y plane defined by the working platform, until the two alignment marks are aligned with each other.

Preferably, the soluble mold has a first alignment mark, and the positioning step of the soluble mold on the polymer layer comprises the steps of: positioning an article for transfer on a working platform, wherein the article for transfer comprises: a substrate positioned on the working platform and the polymer layer positioned on the substrate, and the working platform has a third alignment mark; contacting the soluble mold with the polymer layer; and determining whether the first alignment mark and the third alignment mark are aligned with each other by using a camera positioned on a side of the taking device opposite to the soluble mold or by using another camera positioned on a side of the working platform opposite to the article for transfer; and if the two alignment marks are not aligned with each other, adjusting an x-axis position and a y-axis position of the soluble mold and a θ angle formed between the soluble mold and an x-y plane defined by the working platform, until the two alignment marks are aligned with each other.

Preferably, the soluble mold has a first alignment mark, and the positioning step of the soluble mold on the polymer layer comprises the steps of: positioning an article for transfer on a working platform, wherein the article for transfer comprises: a substrate positioned on the working platform and the polymer layer positioned on the substrate, and the working platform has a third alignment mark; moving a camera to a position between the soluble mold and the article for transfer to determine whether the first alignment mark and the third alignment mark are aligned with each other; and if the two alignment marks are aligned with each other, restoring the position of the camera, and then contacting the soluble mold with the polymer layer; or if the two alignment marks are not aligned with each other, adjusting an x-axis position and a y-axis position of the soluble mold and a θ angle formed between the soluble mold and an x-y plane defined by the working platform, until the two alignment marks are aligned with each other.

Preferably, the soluble mold has a first alignment mark, and the positioning step of the soluble mold on the polymer layer comprises the steps of: positioning an article for transfer on a working platform, wherein the article for transfer comprises: a substrate positioned on the working platform and the polymer layer positioned on the substrate, and the polymer layer has a fourth alignment mark; determining whether the first alignment mark and the fourth alignment mark are aligned with each other by using a camera positioned on a side of the taking device opposite to the soluble mold or by using another camera positioned on a side of the working platform opposite to the article for transfer; and if the two alignment marks are aligned with each other, contacting the soluble mold with the polymer layer; or if the two alignment marks are not aligned with each other, adjusting an x-axis position and a y-axis position of the soluble mold and a θ angle formed between the soluble mold and an x-y plane defined by the working platform, until the two alignment marks are aligned with each other.

Preferably, the soluble mold has a first alignment mark, and the positioning step of the soluble mold on the polymer layer comprises the steps of: positioning an article for transfer on a working platform, wherein the article for transfer comprises: a substrate positioned on the working platform and the polymer layer positioned on the substrate, and the polymer layer has a fourth alignment mark; contacting the soluble mold with the polymer layer; and determining whether the first alignment mark and the fourth alignment mark are aligned with each other by using a camera positioned on a side of the taking device opposite to the soluble mold or by using another camera positioned on a side of the working platform opposite to the article for transfer; and if the two alignment marks are not aligned with each other, adjusting an x-axis position and a y-axis position of the soluble mold and a θ angle formed between the soluble mold and an x-y plane defined by the working platform, until the two alignment marks are aligned with each other.

Preferably, the soluble mold has a first alignment mark, and the positioning step of the soluble mold on the polymer layer comprises the steps of: positioning an article for transfer on a working platform, wherein the article for transfer comprises: a substrate positioned on the working platform and the polymer layer positioned on the substrate, and the polymer layer has a fourth alignment mark; moving a camera to a position between the soluble mold and the article for transfer to determine whether the first alignment mark and the fourth alignment mark are aligned with each other; and if the two alignment marks are aligned with each other, restoring the position of the camera, and then contacting the soluble mold with the polymer layer; or if the two alignment marks are not aligned with each other, adjusting an x-axis position and a y-axis position of the soluble mold and a θ angle formed between the soluble mold and an x-y plane defined by the working platform, until the two alignment marks are aligned with each other.

The present invention also provides an imprinting system, which includes: a working platform and a camera. The working platform is configured for an article for transfer, a soluble mold, and a taking device being deposited thereon, the article for transfer has a substrate and a polymer layer positioned on the substrate, the soluble mold is positioned on the polymer layer of the article for transfer and has a convex-concave pattern and a first alignment mark, and the taking device is adhered to the soluble mold; wherein the substrate has a second alignment mark, the working platform has a third alignment mark, or the polymer layer has a fourth alignment mark. The camera is configured for determining whether the first alignment mark and the second alignment mark are aligned with each other, the first alignment mark and the third alignment mark are aligned with each other, or the first alignment mark and the fourth alignment mark are aligned with each other.

Preferably, the imprinting system further comprises: an infrared (IR) emitter configured for emitting an infrared ray to the first alignment mark and the second alignment mark, to the first alignment mark and the third alignment mark, or to the first alignment mark and the fourth alignment mark.

Preferably, the camera is positioned on a side of the taking device opposite to the soluble mold or positioned on a side of the working platform opposite to the article for transfer.

Preferably, the camera is moveable to a position between the soluble mold and the article for transfer.

According to the present invention, since the support plate is adhered to the soluble mold by using the adhesive, the support plate can maintain the structure of the soluble mold during removing the taking device from the master mold together with the soluble mold, positioning the soluble mold on the polymer layer, applying the first high temperature and the pressure to the soluble mold, applying the second high temperature to the soluble mold, and dissolving the soluble mold. As such, the soluble mold can't be shifted or deformed so that the transferred article has no pattern defects.

### BRIEF DESCRIPTION OF THE DRAWINGS

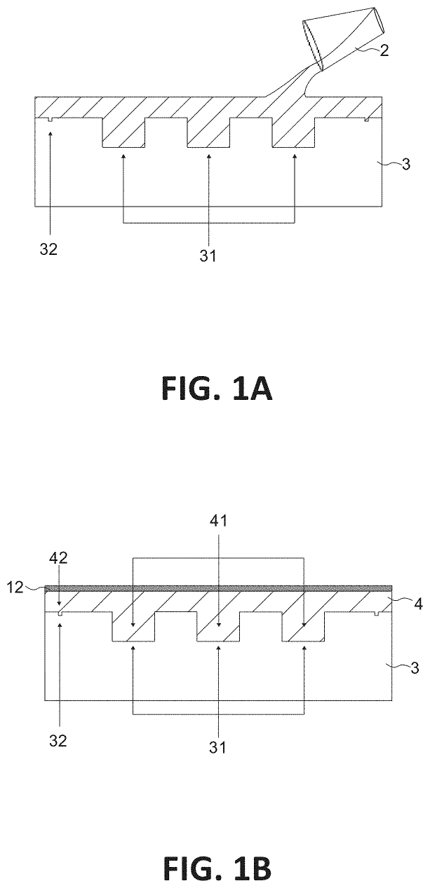

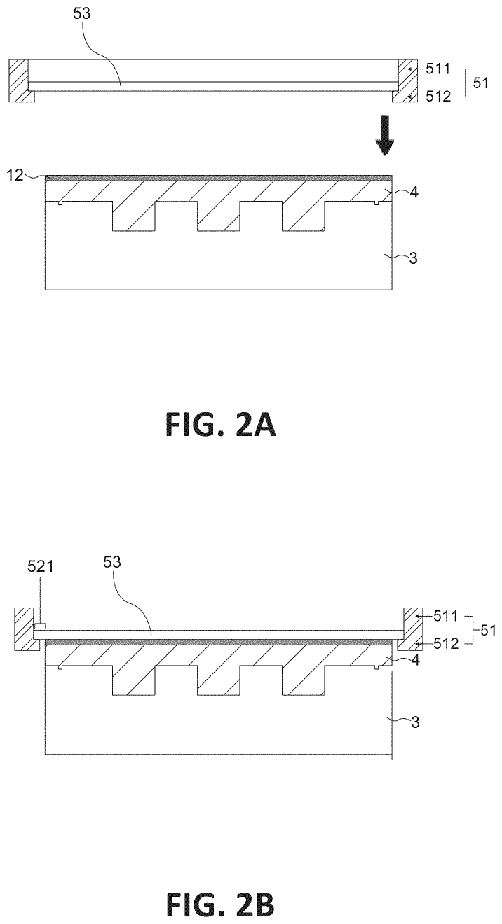

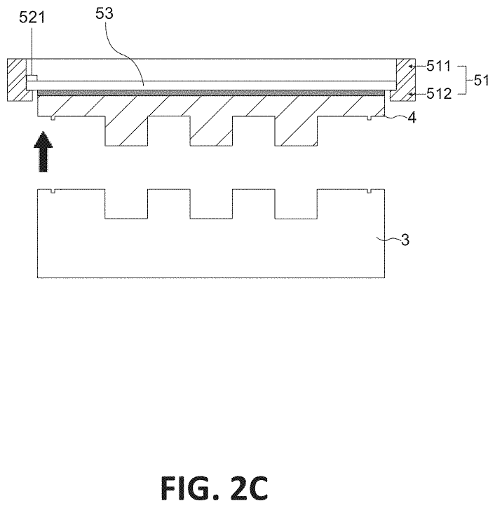

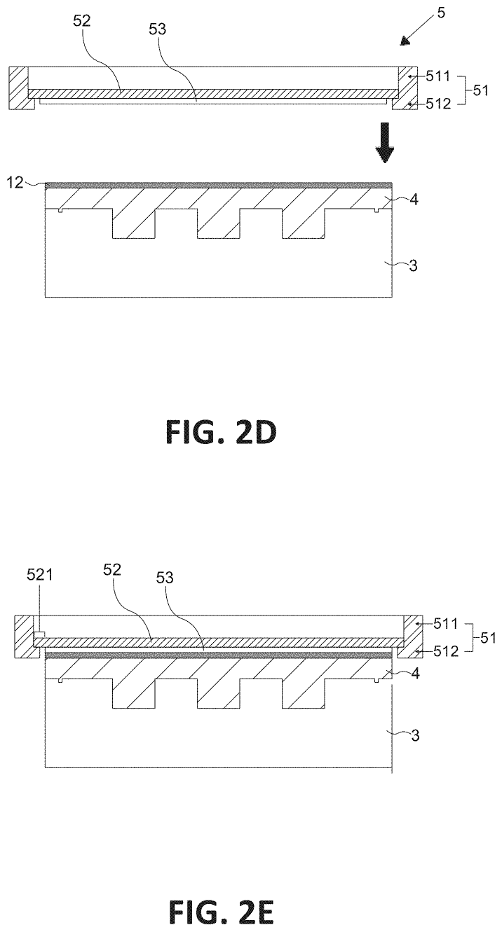

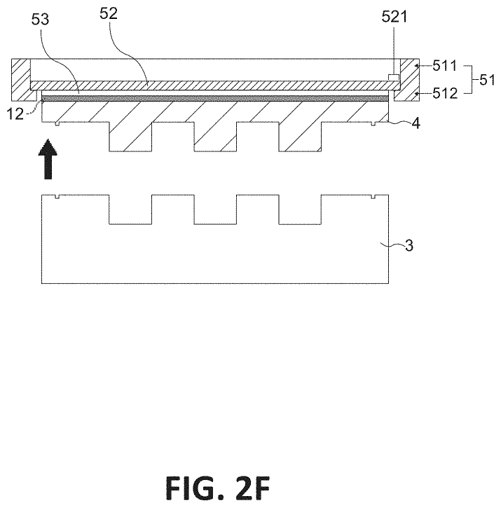

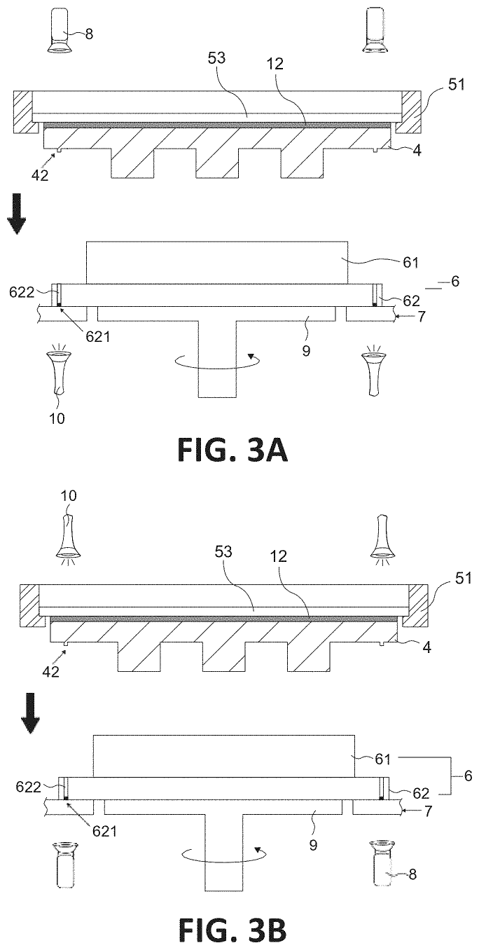

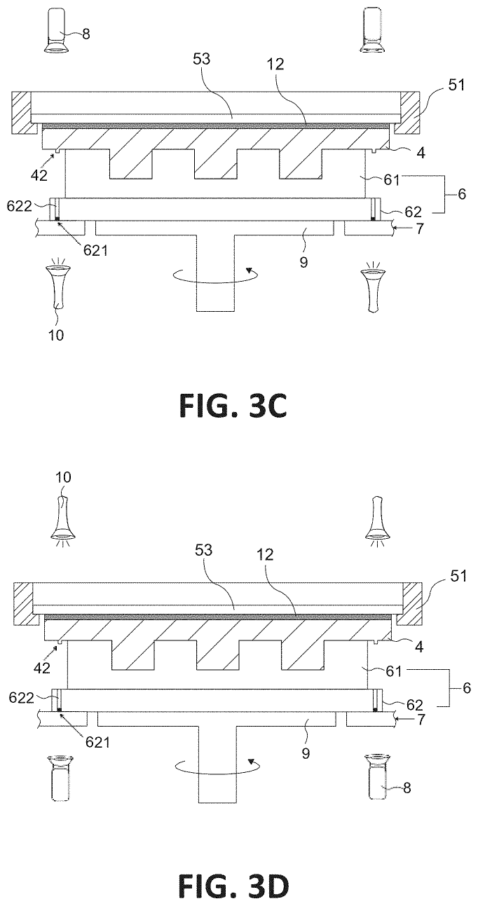

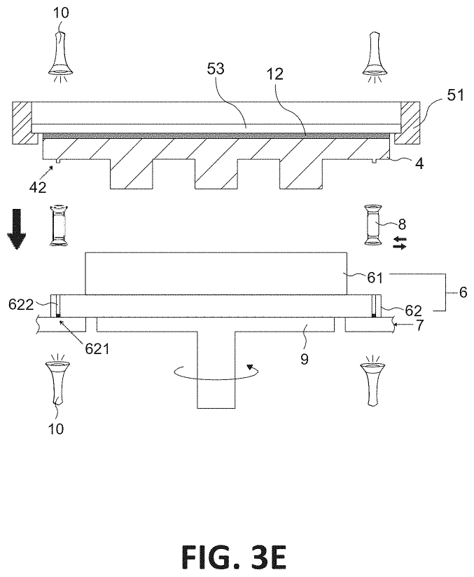

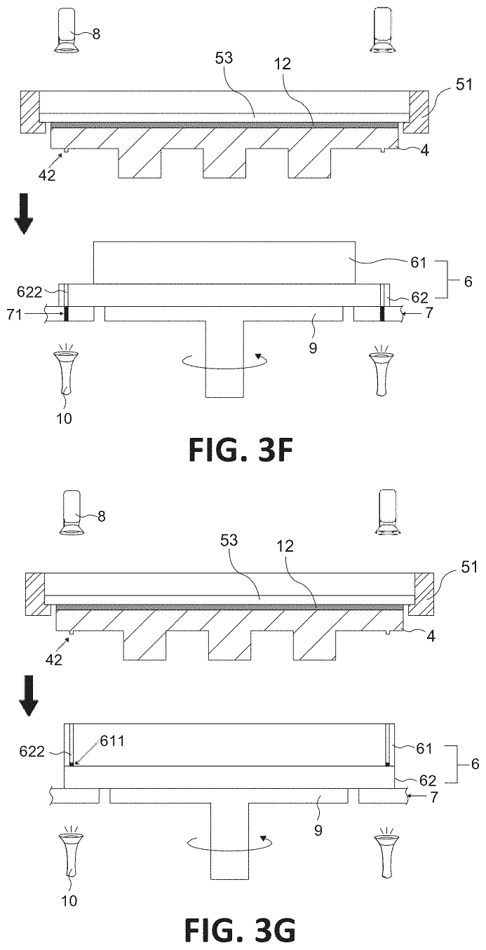

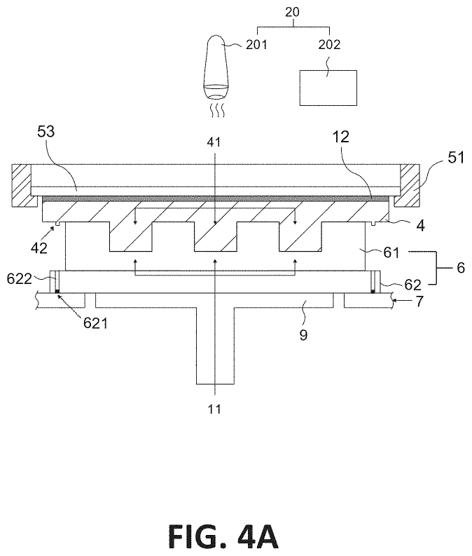

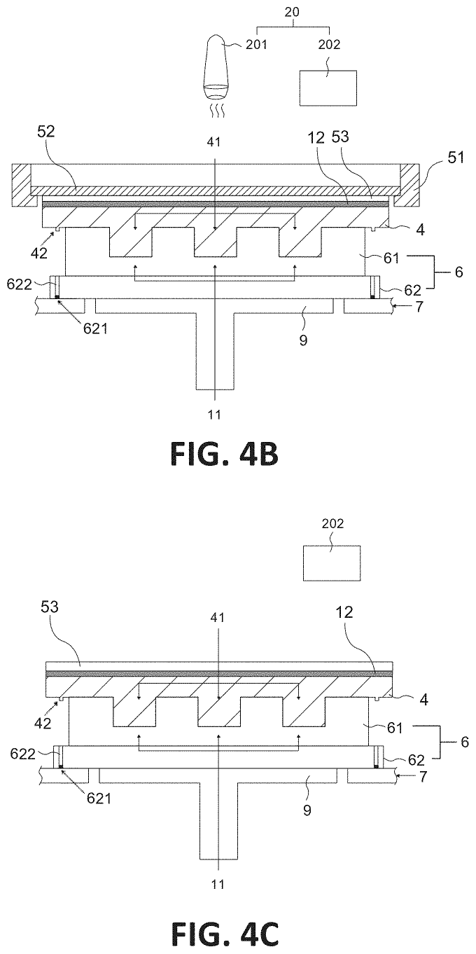

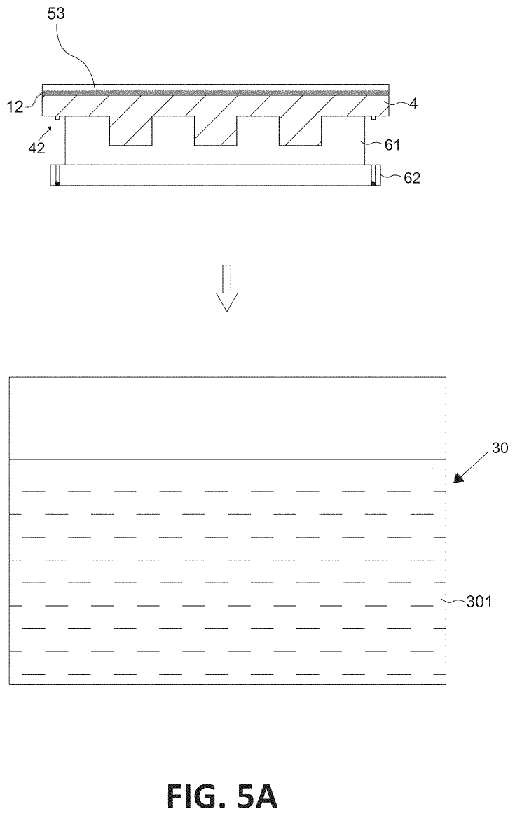

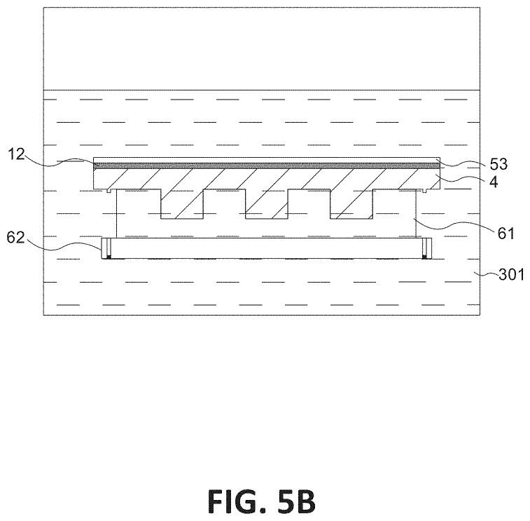

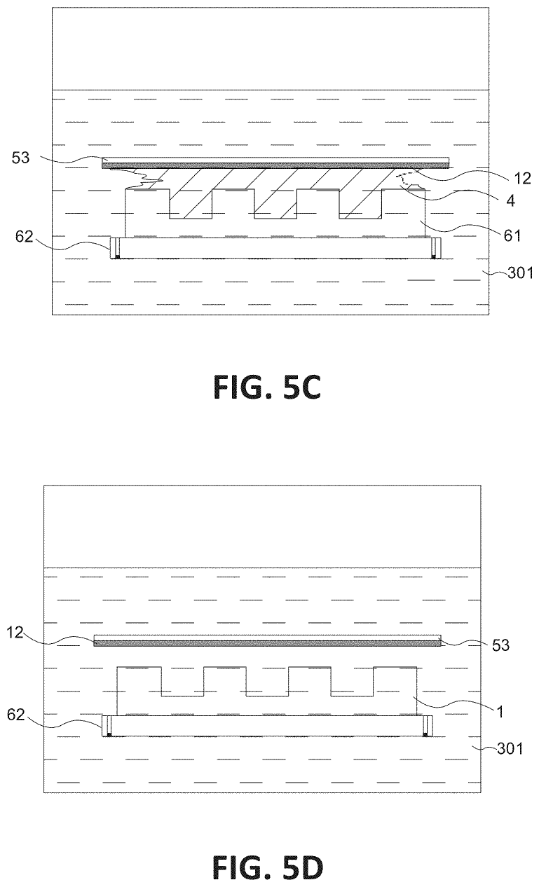

FIGS. 1 to 5 show a series of schematic views of an imprinting method of the present invention:
wherein FIGS. 1A to 1B illustrate the first step of the foregoing imprinting method;

wherein FIGS. 2A to 2F illustrate the second step of the foregoing imprinting method;

wherein FIGS. 3A to 3G illustrate the third step of the foregoing imprinting method;

wherein FIGS. 4A to 4C illustrate the fourth step of the foregoing imprinting method; and

wherein FIGS. 5A to 5D illustrate the fifth step of the foregoing imprinting method.

### DETAILED DESCRIPTION OF THE INVENTION

The detailed description and preferred embodiments of the invention will be set forth in the following content, and provided for people skilled in the art to understand the characteristics of the invention.

An imprinting method according to an embodiment of the present invention is shown in FIGS. 1 to 5, and the detailed steps of the exemplary method are described as below:

The first step of forming a soluble mold (4) on a master mold (3) is depicted in FIGS. 1A to 1B.

As shown in FIG. 1A, a soluble material (2) is added to a master mold (3), and the master mold (3) has a mold structure (31) and a mark structure (32). Then, the soluble material (2) is solidified to form a soluble mold (4), and the soluble mold (4) has a convex-concave pattern (41) corresponding to the mold structure (31) and a first alignment mark (42) corresponding to the mark structure (32). Preferably, the soluble material (2) is selected from the group consisting of: water-soluble polyacrylamide (PAM), polyurethane (PU), polyurea, polyamide (PA), polyester, polyvinylpyrrolidone (PVP), ethylene vinyl alcohol copolymer (EVOH), polyacrylamide-glyoxal polymer, polyacrylic acid (PAA), and any combination thereof, but not limited thereto. Preferably, the thickness of the soluble material (2) on the master mold (3) is from 10 μm to 1,000 μm. Preferably, the soluble mold (4) is also flexible. Preferably, the soluble material (2) is added to the master mold (3) in a solution form, and its concentration in the solution is from 5 wt % to 50 wt %, but not limited thereto. While the concentration is lower than the low limit, the probability for the convex-concave pattern (41) incompleteness may increase so that the convex-concave pattern (41) is defective to lower the imprinting quality. Preferably, the soluble material (2) is added to the master mold (3) by using spin coating or slot-die coating, and the spin rate for spin coating is from 100 rpm to 5,000 rpm, but not limited thereto. Preferably, the master mold (3) is made of silicon.

As shown in FIG. 1B, the soluble material (2) is solidified to form a soluble mold (4), and then an adhesive (12) is positioned on a side of the soluble mold (4) opposite to the master mold (3). Preferably, the adhesive (12) is positioned by using spraying, coating, or dumping, but not limited thereto. Preferably, the adhesive (12) is selected from the group consisting of: light curable adhesive, UV curable adhesive, light-to-heat conversion adhesive, thermosetting adhesive, and water-soluble resin, but not limited thereto. Preferably, the soluble material (2) is solidified by using thermal solidification or light solidification (e.g., UV solidification). Preferably, the temperature for the thermal solidification is from room temperature to 160° C., and the time for the thermal solidification is from 5 minutes to 60 minutes, but not limited thereto. While the time is higher than the upper limit, the peeling difficulty for the soluble mold (4) may increase so that the defects of the convex-concave pattern (41) are formed.

The second step of separating the soluble mold (4) and the master mold (3) is depicted in FIGS. 2A to 2F.

An example of the second step is shown in FIGS. 2A to 2C, wherein a taking device (5) is provided to attach to the adhesive (12), and the taking device (5) comprises a frame (51) and a support plate (53) connected to the frame (51). Another example of the second step is shown in FIGS. 2D to 2F, wherein a taking device (5) is provided to attach to the adhesive (12), and the taking device (5) comprises a frame (51), a tape (52) connected to the frame (51), and a support plate (53) connected to the tape (52). Preferably, the taking device (5) is attached to the adhesive (12) through attachment of the support plate (53) to the adhesive (12). Preferably, the frame (51) is a ring frame, and the ring frame has a support part (511) and an operation part (512) connected to the support part (511). Preferably, the support plate (53) or the tape (52) is connected to the operation part (512). Preferably, the support plate (53) has an enough area to completely cover the adhesive (12) so that the soluble mold (4) can be tightly adhered to the support plate (53) to prevent the soluble mold (4) from being shifted during removing the soluble mold (4) relative to the master mold (3). Preferably, the tape (52) is made of a heat-dissociable foam and a UV-dissociable foam, but not limited thereto. Preferably, the heat-dissociable foam is a polystyrene foam or a polyurethane foam, and its thickness is from 100 μm to 1,000 μm. Preferably, the tape (52) has a protrusion part (521) connected to the operation part (512) of the frame (51). Preferably, the support plate (53) has a protrusion part (521) connected to the operation part (512) of the frame (51).

Afterwards, the taking device (5) is moved so that the soluble mold (4) is moved relative to the master mold (3) together with the taking device (5) to separate the soluble mold (4) and the master mold (3). Preferably, a vertical peeling force or a sideways peeling force is applied to the operation part (512) of the frame (51) to move the taking device (5).

The third step of positioning the soluble mold (4) on a polymer layer (61) is depicted in FIGS. 3A to 3G.

An example of the third step is shown in FIGS. 3A to 3B, wherein a substrate (62) of an article (6) for transfer is positioned on a working platform (7), and the substrate (62) has a second alignment mark (621); then, a polymer layer (61) is formed on the substrate (62); afterwards, it is determined whether the first alignment mark (42) and the second alignment mark (621) of the substrate (62) are aligned with each other by using a camera (8) positioned on a side of the taking device (5) opposite to the soluble mold (4) or by using another camera (8) positioned on a side of the working platform (7) opposite to the article (6) for transfer; finally, if the two alignment marks (42 & 621) are aligned with each other, the soluble mold (4) is contacted with the polymer layer (61) and the next step is performed, or if the two alignment marks (42 & 621) are not aligned with each other, an x-axis position and a y-axis position of the soluble mold (4) and a θ angle formed between the soluble mold (4) and an x-y plane defined by the working platform (7) are adjusted by using a position adjusting element (9), until the two alignment marks (42 & 621) are aligned with each other. Another example of the third step is shown in FIGS. 3C to 3D, wherein a substrate (62) of an article (6) for transfer is positioned on a working platform (7), and the substrate (62) has a second alignment mark (621); then, a polymer layer (61) is formed on the substrate (62); afterwards, the soluble mold (4) is contacted with the polymer layer (61); after which, it is determined whether the first alignment mark (42) and the second alignment mark (621) of the substrate (62) are aligned with each other by using a camera (8) positioned on a side of the taking device (5) opposite to the soluble mold (4) or by using another camera (8) positioned on a side of the working platform (7) opposite to the article (6) for transfer; finally, if the two alignment marks (42 & 621) are aligned with each other, the next step is performed, or if the two alignment marks (42 & 621) are not aligned with each other, an x-axis position and a y-axis position of the soluble mold (4) and a θ angle formed between the soluble mold (4) and an x-y plane defined by the working platform (7) are adjusted by using a position adjusting element (9), until the two alignment marks (42 & 621) are aligned with each other. A further example of the third step is shown in FIG. 3E, wherein a substrate (62) of an article (6) for transfer is positioned on a working platform (7), and the substrate (62) has a second alignment mark (621); then, a polymer layer (61) is formed on the substrate (62); afterwards, a camera (8) is moved to a position between the soluble mold (4) and the article (6) for transfer to determine whether the first alignment mark (42) and the second alignment mark (621) of the substrate (62) are aligned with each other; finally, if the two alignment marks (42 & 621) are aligned with each other, the position of the camera (8) is restored, the soluble mold (4) is contacted with the polymer layer (61), and then the next step is performed, or if the two alignment marks (42 & 621) are not aligned with each other, an x-axis position and a y-axis position of the soluble mold (4) and a θ angle formed between the soluble mold (4) and an x-y plane defined by the working platform (7) are adjusted by using a position adjusting element (9), until the two alignment marks (42 & 621) are aligned with each other.

An example of the third step is shown in FIG. 3F, wherein a substrate (62) of an article (6) for transfer is positioned on a working platform (7), and the working platform (7) has a third alignment mark (71); then, a polymer layer (61) is formed on the substrate (62); afterwards, it is determined whether the first alignment mark (42) and the third alignment mark (71) of the working platform (7) are aligned with each other by using a camera (8) positioned on a side of the taking device (5) opposite to the soluble mold (4) or by using another camera (8) positioned on a side of the working platform (7) opposite to the article (6) for transfer; finally, if the two alignment marks (42 & 71) are aligned with each other, the soluble mold (4) is contacted with the polymer layer (61) and the next step is performed, or if the two alignment marks (42 & 71) are not aligned with each other, an x-axis position and a y-axis position of the soluble mold (4) and a θ angle formed between the soluble mold (4) and an x-y plane defined by the working platform (7) are adjusted by using a position adjusting element (9), until the two alignment marks (42 & 71) are aligned with each other. In another example of the third step, a substrate (62) of an article (6) for transfer is positioned on a working platform (7), and the working platform (7) has a third alignment mark (71); then, a polymer layer (61) is formed on the substrate (62); afterwards, the soluble mold (4) is contacted with the polymer layer (61); after which, it is determined whether the first alignment mark (42) and the third alignment mark (71) of the working platform (7) are aligned with each other by using a camera (8) positioned on a side of the taking device (5) opposite to the soluble mold (4) or by using another camera (8) positioned on a side of the working platform (7) opposite to the article (6) for transfer; finally, if the two alignment marks (42 & 71) are aligned with each other, the next step is performed, or if the two alignment marks (42 & 71) are not aligned with each other, an x-axis position and a y-axis position of the soluble mold (4) and a 0 angle formed between the soluble mold (4) and an x-y plane defined by the working platform (7) are adjusted by using a position adjusting element (9), until the two alignment marks (42 & 71) are aligned with each other. In a further example of the third step, a substrate (62) of an article (6) for transfer is positioned on a working platform (7), and the working platform (7) has a third alignment mark (71); then, a polymer layer (61) is formed on the substrate (62); afterwards, a camera (8) is moved to a position between the soluble mold (4) and the article (6) for transfer to determine whether the first alignment mark (42) and the third alignment mark (71) of the working platform (7) are aligned with each other; finally, if the two alignment marks (42 & 71) are aligned with each other, the position of the camera (8) is restored, the soluble mold (4) is contacted with the polymer layer (61), and then the next step is performed, or if the two alignment marks (42 & 71) are not aligned with each other, an x-axis position and a y-axis position of the soluble mold (4) and a θ angle formed between the soluble mold (4) and an x-y plane defined by the working platform (7) are adjusted by using a position adjusting element (9), until the two alignment marks (42 & 71) are aligned with each other.

An example of the third step is shown in FIG. 3G, wherein a substrate (62) of an article (6) for transfer is positioned on a working platform (7); then, a polymer layer (61) is formed on the substrate (62), and the polymer layer (61) has a fourth alignment mark (611); afterwards, it is determined whether the first alignment mark (42) and the fourth alignment mark (611) of the polymer layer (61) are aligned with each other by using a camera (8) positioned on a side of the taking device (5) opposite to the soluble mold (4) or by using another camera (8) positioned on a side of the working platform (7) opposite to the article (6) for transfer; finally, if the two alignment marks (42 & 611) are aligned with each other, the soluble mold (4) is contacted with the polymer layer (61) and the next step is performed, or if the two alignment marks (42 & 611) are not aligned with each other, an x-axis position and a y-axis position of the soluble mold (4) and a θ angle formed between the soluble mold (4) and an x-y plane defined by the working platform (7) are adjusted by using a position adjusting element (9), until the two alignment marks (42 & 611) are aligned with each other. In another example of the third step, a substrate (62) of an article (6) for transfer is positioned on a working platform (7); then, a polymer layer (61) is formed on the substrate (62), and the polymer layer (61) has a fourth alignment marks (611); afterwards, the soluble mold (4) is contacted with the polymer layer (61); after which, it is determined whether the first alignment mark (42) and the fourth alignment mark (611) of the polymer layer (61) are aligned with each other by using a camera (8) positioned on a side of the taking device (5) opposite to the soluble mold (4) or by using another camera (8) positioned on a side of the working platform (7) opposite to the article (6) for transfer; finally, if the two alignment marks (42 & 611) are aligned with each other, the next step is performed, or if the two alignment marks (42 & 611) are not aligned with each other, an x-axis position and a y-axis position of the soluble mold (4) and a θ angle formed between the soluble mold (4) and an x-y plane defined by the working platform (7) are adjusted by using a position adjusting element (9), until the two alignment marks (42 & 611) are aligned with each other. In a further example of the third step, a substrate (62) of an article (6) for transfer is positioned on a working platform (7); then, a polymer layer (61) is formed on the substrate (62), and the polymer layer (61) has a fourth alignment mark (611); afterwards, a camera (8) is moved to a position between the soluble mold (4) and the article (6) for transfer to determine whether the first alignment mark (42) and the fourth alignment mark (611) of the polymer layer (61) are aligned with each other; finally, if the two alignment marks (42 & 611) are aligned with each other, the position of the camera (8) is restored, the soluble mold (4) is contacted with the polymer layer (61), and then the next step is performed, or if the two alignment marks (42 & 611) are not aligned with each other, an x-axis position and a y-axis position of the soluble mold (4) and a θ angle formed between the soluble mold (4) and an x-y plane defined by the working platform (7) are adjusted by using a position adjusting element (9), until the two alignment marks (42 & 611) are aligned with each other.

Preferably, the polymer layer (61) is formed by coating a polymer material having a glass transition temperature lower than that of the soluble mold (4) with spinning onto the substrate (62), or by coating a polymer material having a glass transition temperature lower than that of the soluble mold (4) with spinning onto the substrate (62) and then baking the polymer material. Preferably, the glass transition temperature of the polymer material is from 20° C. to 150° C., the spinning rate is from 1,000 rpm to 5,000 rpm, and the spinning thickness is from 0.05 μm to 1,000 μm. It is noted that it is determined whether the baking is performed based on the polymer material properties. Preferably, the baking temperature is from 80° C. to 150° C. and the baking time is from 3 minutes to 5 minutes. Besides spin-coating, the polymer layer (61) may be formed onto the substrate (62) with affixing by using an affixing element (not shown). The second alignment mark (621) may be formed on a surface of the substrate (62) opposite to the soluble mold (4) or formed on another surface thereof opposite to the working platform (7). While the second alignment mark (621) of the substrate (62) is formed on a surface of the substrate (62) opposite to the soluble mold (4), the substrate (62) may interfere with an image of the first alignment mark (42) and the second alignment mark (621) captured by the camera (8). Therefore, a via hole (622) may be formed on the substrate (62) to expose the second alignment mark (621). For more conveniently capturing the image of the first alignment mark (42) and the second alignment mark (621), the substrate (62) is preferably a transparent substrate. While the third alignment mark (71) is positioned on the working platform (7), the substrate (62) may interfere with an image of the first alignment mark (42) and the third alignment mark (71) captured by the camera (8). In order to prevent this problem, a via hole (622) may be formed on the substrate (62) to expose the third alignment mark (71). For more conveniently capturing the image of the first alignment mark (42) and the third alignment mark (71), the substrate (62) is preferably a transparent substrate. The fourth alignment mark (611) may be formed on a surface of the polymer layer (61) opposite to the soluble mold (4) or formed on another surface thereof opposite to the working platform (7). While the fourth alignment mark (611) of the polymer layer (61) is formed on a surface of the polymer layer (61) opposite to the soluble mold (4), the substrate (62) may interfere with an image of the first alignment mark (42) and the fourth alignment mark (611) captured by the camera (8). Therefore, a via hole (622) may be formed on the substrate (62) to expose the fourth alignment mark (611). For more conveniently capturing the image of the first alignment mark (42) and the fourth alignment mark (611), the substrate (62) is preferably a transparent substrate.

In order to avoid the insufficient image definition of the first alignment mark (42) and the second alignment mark (621) resulted from light reflection noise, an infrared emitter (10) may be configured for emitting the first alignment mark (42) and the second alignment mark (621). In order to avoid the insufficient image definition of the first alignment mark (42) and the third alignment mark (71) resulted from light reflection noise, an infrared emitter (10) may be configured for emitting the first alignment mark (42) and the third alignment mark (621). In order to avoid the insufficient image definition of the first alignment mark (42) and the fourth alignment mark (611) resulted from light reflection noise, an infrared emitter (10) may be configured for emitting the first alignment mark (42) and the fourth alignment mark (611). Any infrared emitter (10) is preferably positioned on a side of the taking device (5) opposite to the soluble mold (4) or positioned on a side of the working platform (7) opposite to the article (6) for imprint, but not limited thereto.

The fourth step of applying a high temperature and a pressure to the soluble mold (4) to solidify the polymer layer (61) is depicted in FIGS. 4A to 4C.

An example of the fourth step is shown in FIG. 4A, wherein a high temperature and a pressure is applied to the soluble mold (4) by using an imprinting element (20) to allow the polymer layer (61) to have a transferred patter (11) corresponding to the convex-concave pattern (41) and to be solidified. Additionally, the frame (51) and the support plate (53) separate. Since the support plate (53) is still stably adhered to the soluble mold (4) after the polymer layer (61) is solidified and after the frame (51) and the support plate (53) separate, the structural stability of the soluble mod (4) can be maintained so that the first alignment mark (42) is not shifted to affect the shape of the polymer layer (61). Specifically, since the support plate (53) is still stably adhered to the soluble mold (4) before the soluble mold (4) is contacted with the polymer layer (61), after the polymer layer (61) is solidified, and after the frame (51) and the support plate (53) separate, the structural stability of the soluble mod (4) can be maintained. As shown in FIG. 4A, the taking device (5) according to the foregoing example comprises the frame (51) and the support plate (53). Preferably, the applied high temperature can make the temperature of the polymer layer (61) reach to its glass transition temperature and the applied pressure can make the polymer material fully flow into the convex-concave pattern (41); then, the applied high temperature can make the polymer material solidified so that the transferred pattern (11) of the polymer layer (61) completely corresponds to the convex-concave pattern (41). Preferably, the time for the high temperature and pressure applying step is from 1 minute to 20 minutes, but not limited thereto. Preferably, the applied high temperature is from 50° C. to 160° C., but not limited thereto. It is noted that the time range for the high temperature and pressure applying step and the temperature range of the applied high temperature are determined according to the polymer material; generally, it is the principle that the top portion of the polymer layer (61) doesn't melt and the transferred pattern (11) is formed without any defects. Preferably, the pressure applying is performed by applying a positive pressure to a surface of the soluble mold (4) opposite to the polymer layer (61); applying a negative pressure to a surface of the soluble mold (4) facing the polymer layer (61); or simultaneously applying a positive pressure to a surface of the soluble mold (4) opposite to the polymer layer (61) and a negative pressure to a surface of the soluble mold (4) facing the polymer layer (61). Preferably, the positive pressure is from +20 kPa to +600 kPa, and the negative pressure is from −10 kPa to −101.3 kPa, but not limited thereto. It is noted that applied negative pressure can lead to the separation of the volatile solvent released by heat from the polymer layer (61) so as to avoid the released volatile solvent from remaining in the polymer layer (61) and to avoid the transferred pattern (11) from being formed with defects. Also shown in FIG. 4A, the imprinting element (20) preferably includes a heating element (201) configured for providing the high temperature and a blowing element (202) configured for providing the pressure, but not limited thereto.

Another example of the fourth step is shown in FIGS. 4B to 4C. As shown in FIG. 4B, a first high temperature and a pressure is firstly applied to the soluble mold (4) by using an imprinting element (20) to allow the polymer layer (61) to have a transferred patter (11) corresponding to the convex-concave pattern (41) and the tape (52) and the support plate (53) to separate. While the taking device (5) comprises the frame (51) and the tape (52), the tape (52) is made of a heat-dissociable foam, and the dissociation temperature (preferably from 80° C. to 150° C.) of the tape (52) is lower than the first high temperature, the applied first high temperature can make the tape dissociated. Additionally, the applied first high temperature can make the temperature of the polymer layer (61) reach to its glass transition temperature and the applied pressure can make the polymer material fully flow into the convex-concave pattern (41). Preferably, the time for the first high temperature and pressure applying step is from 0.5 minute to 30 minutes, but not limited thereto. Preferably, the applied first high temperature is from 60° C. to 150° C., but not limited thereto. It is noted that the time range for the first high temperature and pressure applying step and the temperature range of the applied first high temperature are determined according to the polymer material; generally, it is the principle that the top portion of the polymer layer (61) doesn't melt and the transferred pattern (11) is formed without any defects. Preferably, the pressure applying is performed by applying a positive pressure to a surface of the soluble mold (4) opposite to the polymer layer (61); applying a negative pressure to a surface of the soluble mold (4) facing the polymer layer (61); or simultaneously applying a positive pressure to a surface of the soluble mold (4) opposite to the polymer layer (61) and a negative pressure to a surface of the soluble mold (4) facing the polymer layer (61). Preferably, the positive pressure is from +20 kPa to +600 kPa, and the negative pressure is from −10 kPa to −101.3 kPa, but not limited thereto. It is noted that applied negative pressure can lead to the separation of the volatile solvent released by heat from the polymer layer (61) so as to avoid the released volatile solvent from remaining in the polymer layer (61) and to avoid the transferred pattern (11) from being formed with defects. Also shown in FIG. 4B, the imprinting element (20) preferably includes a heating element (201) configured for providing the first high temperature and a blowing element (202) configured for providing the pressure, but not limited thereto.

As shown in FIG. 4C, a second high temperature is applied to the soluble mold (4) by using an imprinting element (20), the first high temperature being different from the second high temperature, to allow the polymer layer (61) to be solidified. Preferably, the applied second high temperature can make the temperature of the polymer layer (61) reach to its solidification temperature so that the polymer material is crosslinked to be solidified. As such, the elasticity of the polymer layer (61) can decrease so that the transferred pattern (11) of the polymer layer (61) completely corresponds to the convex-concave pattern (41). Preferably, the time for the second high temperature applying step is from 1 minute to 600 minutes, but not limited thereto. Preferably, the second temperature is from 60° C. to 180° C., but not limited thereto. The second high temperature is especially applied for the condition that the polymer material is thermosetting resin (e.g., epoxy resin). Generally, the applied second high temperature can avoid the polymer layer (61) from deformation when the later-obtained transferred article (1) is positioned at a temperature lower than the second high temperature. As shown in FIG. 4C, the second high temperature is preferably provided by the heating element (201) of the imprinting element (20). It is noted that since the support plate (53) is tightly adhered to the soluble mold (4) during applying the first high temperature and during applying the second high temperature, the structure of the soluble mold (4) can be maintained during these heating steps so that the soluble mold (4) is not shifted or deformed. It is also noted that the polymer layer (61) can be solidified at a relatively low temperature for a relatively longer period. That is, the first high temperature may be higher than the second high temperature. Preferably, while the first high temperature is higher than the second high temperature, the time for the first high temperature applying step is greater than that for the second high temperature applying step, the time for the first high temperature applying step is equivalent to that for the second high temperature applying step, or the time for the first high temperature applying step is lower than that for the second high temperature applying step. Preferably, while the first high temperature is lower than the second high temperature, the time for the first high temperature applying step is greater than that for the second high temperature applying step, the time for the first high temperature applying step is equivalent to that for the second high temperature applying step, or the time for the first high temperature applying step is lower than that for the second high temperature applying step.

The fifth step of dissolving the soluble mold (4) by using a solvent (301) to separate the solidified polymer layer (61) and the support plate (53) is depicted in FIGS. 5A to 5D.

As shown in FIGS. 5A to 5D, a solvent (301) is provided by using a dissolving element (30) to dissolve the soluble mold (4) to allow the solidified polymer layer (61) and the support plate (53) to separate so that a transferred article (1) having the transferred pattern (11) is obtained. It is noted that the solvent (301) is determined according to the material of the soluble mold (4). Preferably, while the soluble mold (4) is made of water-soluble polyacrylamide, polyurethane, polyurea, polyamide, polyester, polyvinylpyrrolidone, ethylene vinyl alcohol copolymer, polyacrylamide-glyoxal polymer, or polyacrylic acid, the solvent (301) is water, but not limited thereto.

Preferably, the solvent (301) dissolves the soluble mold (4) on the working platform (7) to separate the solidified polymer layer (61) and the support plate (53). Preferably, the frame (51) is removed relative to the support plate (53) after the polymer player (601) is solidified and before the soluble mold (4) is dissolved. Preferably, the frame (51) and the tape (52) connected to the frame (51) are removed relative to the support plate (53) after the polymer player (601) is solidified and before the soluble mold (4) is dissolved. Although it is described previously that the solvent (301) dissolves the soluble mold (4) on the working platform (7), the solvent (301) may dissolve the soluble mold (4) at any place out of the working platform (7). Preferably, the entity of the substrate (62), the solidified polymer layer (61) positioned on the substrate (62), the soluble mold (4), and the support plate (53) is put into a container having the solvent (301) to allow the solvent (301) to dissolve the soluble mold (4). As such, the solidified polymer layer (61) and the support plate (53) separate so that the transferred article (1) having the transferred pattern (11) is obtained.

As above, since the support plate (53) is adhered to the soluble mold (4) by using the adhesive (12), the support plate (53) can maintain the structure of the soluble mold (4) during removing the taking device (5) from the master mold (3) together with the soluble mold (4), positioning the soluble mold (4) on the polymer layer (61), applying the first high temperature and the pressure to the soluble mold (4), applying the second high temperature to the soluble mold (4), and dissolving the soluble mold (4). As such, the soluble mold (4) can't be shifted or deformed so that the transferred article (1) has no pattern defects.

While the invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. An imprinting method, comprising:
adding a soluble material to a master mold;
solidifying the soluble material to form a soluble mold, the soluble mold having a convex-concave pattern;
positioning an adhesive on a side of the soluble mold opposite to the master mold;
attaching a taking device to the adhesive, the taking device comprising a frame, a tape connected to the frame, and a support plate connected to the tape, wherein the taking device is attached to the adhesive through contact of the support plate with the adhesive;
removing the taking device from the master mold together with the soluble mold;
positioning the soluble mold on a polymer layer;
applying a first high temperature and a pressure to the soluble mold to form a transferred pattern corresponding to the convex-concave pattern on the polymer layer and separate the support plate and the tape;
applying a second high temperature to the soluble mold to solidify the polymer layer, wherein the first high temperature is different from the second high temperature; and
dissolving the soluble mold by using a solvent to separate the solidified polymer layer and the support plate so as to form a transferred article having the transferred pattern.

2. The imprinting method as claimed in claim 1, wherein the first high temperature is from 60° C. to 150° C., and the second high temperature is from 60° C. to 180° C.

3. The imprinting method as claimed in claim 2, wherein time for the applying step of the first high temperature and the pressure is from 0.5 minute to 30 minutes, and time for the applying step of the second high temperature is from 1 minute to 600 minutes.

4. The imprinting method as claimed in claim 3, wherein the first high temperature is higher than the second high temperature; wherein the time for the applying step of the first high temperature is greater than that for the applying step of the second high temperature, the time for the applying step of the first high temperature is equivalent to that for the applying step of the second high temperature, or the time for the applying step of the first high temperature is lower than that for the applying step of the second high temperature.

5. The imprinting method as claimed in claim 3, wherein the first high temperature is lower than the second high temperature; wherein the time for the applying step of the first high temperature is greater than that for the applying step of the second high temperature, the time for the applying step of the first high temperature is equivalent to that for the applying step of the second high temperature, or the time for the applying step of the first high temperature is lower than that for the applying step of the second high temperature.

6. The imprinting method as claimed in claim 1, wherein the soluble mold has a first alignment mark; wherein the positioning step of the soluble mold on the polymer layer comprises the steps of: positioning an article for transfer on a working platform, wherein the article for transfer comprises: a substrate positioned on the working platform and the polymer layer positioned on the substrate, and the substrate has a second alignment mark; determining whether the first alignment mark and the second alignment mark are aligned with each other by using a camera positioned on a side of the taking device opposite to the soluble mold or by using another camera positioned on a side of the working platform opposite to the article for transfer; and if the two alignment marks are aligned with each other, contacting the soluble mold with the polymer layer; or if the two alignment marks are not aligned with each other, adjusting an x-axis position and a y-axis position of the soluble mold and a 0 angle formed between the soluble mold and an x-y plane defined by the working platform, until the two alignment marks are aligned with each other; the positioning step of the soluble mold on the polymer layer comprises the steps of: positioning an article for transfer on a working platform, wherein the article for transfer comprises: a substrate positioned on the working platform and the polymer layer positioned on the substrate, and the substrate has a second alignment mark; contacting the soluble mold with the polymer layer; and determining whether the first alignment mark and the second alignment mark are aligned with each other by using a camera positioned on a side of the taking device opposite to the soluble mold or by using another camera positioned on a side of the working platform opposite to the article for transfer; and if the two alignment marks are not aligned with each other, adjusting an x-axis position and a y-axis position of the soluble mold and a θ angle formed between the soluble mold and an x-y plane defined by the working platform, until the two alignment marks are aligned with each other; or the positioning step of the soluble mold on the polymer layer comprises the steps of: positioning an article for transfer on a working platform, wherein the article for transfer comprises: a substrate positioned on the working platform and the polymer layer positioned on the substrate, and the substrate has a second alignment mark; moving a camera to a position between the soluble mold and the article for transfer to determine whether the first alignment mark and the second alignment mark are aligned with each other; and if the two alignment marks are aligned with each other, restoring the position of the camera, and then contacting the soluble mold with the polymer layer; or if the two alignment marks are not aligned with each other, adjusting an x-axis position and a y-axis position of the soluble mold and a θ angle formed between the soluble mold and an x-y plane defined by the working platform, until the two alignment marks are aligned with each other.

7. The imprinting method as claimed in claim 1, wherein the soluble mold has a first alignment mark; wherein the positioning step of the soluble mold on the polymer layer comprises the steps of: positioning an article for transfer on a working platform, wherein the article for transfer comprises: a substrate positioned on the working platform and the polymer layer positioned on the substrate, and the working platform has a third alignment mark; determining whether the first alignment mark and the third alignment mark are aligned with each other by using a camera positioned on a side of the taking device opposite to the soluble mold or by using another camera positioned on a side of the working platform opposite to the article for transfer; and if the two alignment marks are aligned with each other, contacting the soluble mold with the polymer layer; or if the two alignment marks are not aligned with each other, adjusting an x-axis position and a y-axis position of the soluble mold and a 0 angle formed between the soluble mold and an x-y plane defined by the working platform, until the two alignment marks are aligned with each other; the positioning step of the soluble mold on the polymer layer comprises the steps of: positioning an article for transfer on a working platform, wherein the article for transfer comprises: a substrate positioned on the working platform and the polymer layer positioned on the substrate, and the working platform has a third alignment mark; contacting the soluble mold with the polymer layer; and determining whether the first alignment mark and the third alignment mark are aligned with each other by using a camera positioned on a side of the taking device opposite to the soluble mold or by using another camera positioned on a side of the working platform opposite to the article for transfer; and if the two alignment marks are not aligned with each other, adjusting an x-axis position and a y-axis position of the soluble mold and a θ angle formed between the soluble mold and an x-y plane defined by the working platform, until the two alignment marks are aligned with each other; or the positioning step of the soluble mold on the polymer layer comprises the steps of: positioning an article for transfer on a working platform, wherein the article for transfer comprises: a substrate positioned on the working platform and the polymer layer positioned on the substrate, and the working platform has a third alignment mark; moving a camera to a position between the soluble mold and the article for transfer to determine whether the first alignment mark and the third alignment mark are aligned with each other; and if the two alignment marks are aligned with each other, restoring the position of the camera, and then contacting the soluble mold with the polymer layer; or if the two alignment marks are not aligned with each other, adjusting an x-axis position and a y-axis position of the soluble mold and a θ angle formed between the soluble mold and an x-y plane defined by the working platform, until the two alignment marks are aligned with each other.

8. The imprinting method as claimed in claim 1, wherein the soluble mold has a first alignment mark; wherein the positioning step of the soluble mold on the polymer layer comprises the steps of: positioning an article for transfer on a working platform, wherein the article for transfer comprises: a substrate positioned on the working platform and the polymer layer positioned on the substrate, and the polymer layer has a fourth alignment mark; determining whether the first alignment mark and the fourth alignment mark are aligned with each other by using a camera positioned on a side of the taking device opposite to the soluble mold or by using another camera positioned on a side of the working platform opposite to the article for transfer; and if the two alignment marks are aligned with each other, contacting the soluble mold with the polymer layer; or if the two alignment marks are not aligned with each other, adjusting an x-axis position and a y-axis position of the soluble mold and a θ angle formed between the soluble mold and an x-y plane defined by the working platform, until the two alignment marks are aligned with each other; the positioning step of the soluble mold on the polymer layer comprises the steps of: positioning an article for transfer on a working platform, wherein the article for transfer comprises: a substrate positioned on the working platform and the polymer layer positioned on the substrate, and the polymer layer has a fourth alignment mark; contacting the soluble mold with the polymer layer; and determining whether the first alignment mark and the fourth alignment mark are aligned with each other by using a camera positioned on a side of the taking device opposite to the soluble mold or by using another camera positioned on a side of the working platform opposite to the article for transfer; and if the two alignment marks are not aligned with each other, adjusting an x-axis position and a y-axis position of the soluble mold and a θ angle formed between the soluble mold and an x-y plane defined by the working platform, until the two alignment marks are aligned with each other; or the positioning step of the soluble mold on the polymer layer comprises the steps of: positioning an article for transfer on a working platform, wherein the article for transfer comprises: a substrate positioned on the working platform and the polymer layer positioned on the substrate, and the polymer layer has a fourth alignment mark; moving a camera to a position between the soluble mold and the article for transfer to determine whether the first alignment mark and the fourth alignment mark are aligned with each other; and if the two alignment marks are aligned with each other, restoring the position of the camera, and then contacting the soluble mold with the polymer layer; or if the two alignment marks are not aligned with each other, adjusting an x-axis position and a y-axis position of the soluble mold and a θ angle formed between the soluble mold and an x-y plane defined by the working platform, until the two alignment marks are aligned with each other.

9. The imprinting method as claimed in claim 6, further comprises:
emitting an infrared ray to the first alignment mark and the second alignment mark to avoid insufficient image definition of the first alignment mark and the second alignment mark resulted from light reflection noise.

10. The imprinting method as claimed in claim 7, further comprises:
emitting an infrared ray to the first alignment mark and the third alignment mark to avoid insufficient image definition of the first alignment mark and the third alignment mark resulted from light reflection noise.

11. The imprinting method as claimed in claim 8, further comprises:
emitting an infrared ray to the first alignment mark and the fourth alignment mark to avoid insufficient image definition of the first alignment mark and the fourth alignment mark resulted from light reflection noise.

12. The imprinting method as claimed in claim 9, wherein a via hole is formed on the substrate to expose the second alignment mark.

13. The imprinting method as claimed in claim 10, wherein a via hole is formed on the substrate to expose the third alignment mark.

14. The imprinting method as claimed in claim 11, wherein a via hole is formed on the substrate to expose the fourth alignment mark.

15. The imprinting method as claimed in claim 1, wherein the soluble mold is made of water-soluble polyacrylamide, polyurethane, polyurea, polyamide, polyester, polyvinylpyrrolidone, ethylene vinyl alcohol copolymer, polyacrylamide-glyoxal polymer, or polyacrylic acid, and the solvent is water.
